(19) United States
(12) Patent Application Publication
(10) Pub. No.: US 2026/0085419 A1
(43) Pub. Date: Mar. 26, 2026

(54) MOLYBDENUM PRECURSOR COMPOUND, METHOD FOR PRODUCING SAME, AND METHOD FOR DEPOSITING MOLYBDENUM-CONTAINING THIN FILM USING SAME

(71) Applicants: UP CHEMICAL CO., LTD., Pyeongtaek-si (KR); SK HYNIX INC., Icheon-si (KR)

(72) Inventors: Myeong Ho KIM, Pyeongtaek-si (KR); Jin Sik KIM, Pyeongtaek-si (KR); In Jae LEE, Pyeongtaek-si (KR); Supill CHUN, Icheon-si (KR); Sang Hyun LEE, Icheon-si (KR); Dong Kyun LEE, Icheon-si (KR)

(21) Appl. No.: 19/109,582

(22) PCT Filed: Oct. 30, 2023
(86) PCT No.: PCT/KR2023/017035

§ 371 Date: Mar. 7, 2025

(30) Foreign Application Priority Data
Oct. 31, 2022 (KR) 10-2022-0142302

(51) Int. Cl. C23C 16/455; C23C 16/34; C23C 16/40

(52) U.S. Cl. CPC C23C 16/45553; C23C 16/34; C23C 16/405

(57) ABSTRACT

A molybdenum precursor compound represented by chemical formula 1 is advantageous for manufacturing processes due to being in a liquid state at room temperature, has excellent thermal stability, and can easily form molybdenum-containing thin films by chemical vapor deposition as well as atomic layer deposition.

### TECHNICAL FIELD

The present invention relates to a molybdenum precursor compound, a method for preparing the molybdenum precursor compound, a precursor composition for forming a molybdenum thin film comprising the molybdenum precursor compound, and a method for depositing a molybdenum-containing thin film using the precursor compound.

### BACKGROUND ART

Molybdenum (Mo)-containing thin films are used as diffusion barrier layers of metal wiring, gate metals, electrodes, and the like in a semiconductor process. They are widely used for industrial purposes as hard coating materials, sensors, channel layers, and catalysts.

In particular, since a pure molybdenum-containing thin film has a large work function, it can be used as an important metallic material that can suppress the leakage current of capacitors that require a high dielectric constant by the integration in DRAM. In addition, a molybdenum-containing thin film can replace tungsten (W) metal currently used by virtue of its low resistance or can be used as a diffusion barrier of tungsten (W) metal in 3D NAND flash memory. Further, a molybdenum-containing thin film can be used as a seed layer for growing molybdenum and as a diffusion barrier layer in a metal process in a non-memory field such as a logic device.

A molybdenum-containing oxide thin film (MoO₃) is a material applied in various fields by virtue of its excellent physical and chemical properties. In particular, since it is known to have sensing capabilities for gases such as NO₂ and NH₃, its application as a gas sensor is being widely studied.

In addition, when MoO₃ is deposited using ALD, a thin film with a high surface ratio can be deposited, and a complex three-dimensional structure can be implemented, thereby increasing sensing capability. In addition, methods to increase sensing capabilities by combining various oxides such as MoO₃, WO₃, and TiO₂ are being actively studied in the oxide-based gas sensor research. Since it is relatively easy to control the composition in atomic layer deposition (ALD), it is understood to be applicable to thin film deposition.

Meanwhile, products having a complex shape such as a high aspect ratio and a three-dimensional structure are variously developed in the memory field and non-memory field, and molybdenum-containing metal films, molybdenum-containing oxide thin films, and molybdenum-containing nitride thin films suitable therefor are required.

Molybdenum precursor compounds such as MoCl₅ and MoO₂Cl₂ are known to be currently used for such molybdenum-containing thin films. Since these precursors are solid precursors, it may be difficult to supply a source, thereby causing difficulties in the process, and there may be a problem in that the mass productivity is low.

In addition, Mo(^{t}BuN)₂(NMe₂)₂ and Mo(NMeEt)₄ are known as molybdenum precursor compounds. Although these precursor compounds are precursors in a liquid form, there is a limitation in forming a molybdenum-containing thin film having excellent film quality due to their poor thermal stability.

Therefore, there is a demand for developing a molybdenum precursor compound capable of forming a molybdenum-containing metal film, a molybdenum-containing oxide thin film, or a molybdenum-containing nitride thin film that has excellent thermal stability, whereby it can exhibit excellent properties even at high temperatures, is suitable for the processing temperatures for various application fields such as memory field and non-memory field, and has excellent uniformity and quality. Further, there is a need for developing a novel molybdenum precursor compound that can be used for atomic layer deposition (ALD) capable of overcoming a high step ratio.

### PRIOR ART DOCUMENTS

(Patent Document 1) Korean Laid-open Patent Publication No. 2019-0024823

### DISCLOSURE OF INVENTION

### Technical Problem

An object of the present invention is to solve the above problems, thereby providing a precursor compound capable of being present in a liquid state at room temperature, being vaporized by heating to be applied to a bypass process for supplying a source, and depositing molybdenum-containing metal films, molybdenum-containing oxide thin films, or molybdenum-containing nitride thin films at various temperatures.

In addition, another object of the present invention is to provide a method for depositing a molybdenum-containing metal film, a molybdenum-containing oxide thin film, or a molybdenum-containing nitride thin film using the precursor compound by atomic layer deposition.

In addition, another object of the present invention is to provide a technique of safely synthesizing a precursor compound for depositing a molybdenum-containing metal film, a molybdenum-containing oxide thin film, or a molybdenum-containing nitride thin film by atomic layer deposition.

### Solution to Problem

In order to accomplish the above object, the present invention provides a molybdenum precursor compound represented by the following Formula 1:

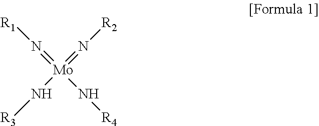

In Formula 1, R₁ to R₄ are each independently selected from substituted or unsubstituted C₅-C₁₀ linear and branched alkyl groups.

In addition, the present invention provides a composition for forming a molybdenum-containing thin film that comprises the molybdenum precursor compound.

In addition, the present invention provides a method for preparing a molybdenum precursor compound represented by the above Formula 1 that comprises reacting a compound represented by the following Formula A with a compound represented by the following Formula B and a compound represented by the following Formula C in a solvent.

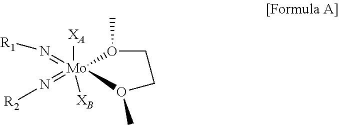

In Formula A, R₁ and R₂ are each independently selected from substituted or unsubstituted C₅-C₁₀ linear and branched alkyl groups, and X_{A} and X_{B} are each independently a halogen element,

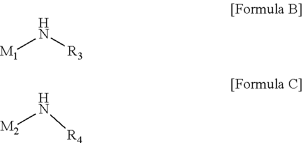

In Formulae B and C, M₁ and M₂ are each independently an alkali metal or alkaline earth metal, and R₃ and R₄ are each independently selected from substituted or unsubstituted C₅-C₁₀ linear and branched alkyl groups.

In addition, the present invention provides a molybdenum-containing thin film formed using the molybdenum precursor compound.

In addition, the present invention provides a method for depositing a molybdenum-containing thin film that comprises depositing a molybdenum-containing thin film on a substrate using the molybdenum precursor compound.

### Advantageous Effects of Invention

The molybdenum precursor compound according to the present invention is present in a liquid state at room temperature, which is advantageous for the manufacturing process, has a low resistivity, and is excellent in thermal stability. It is possible to readily form a molybdenum-containing thin film by atomic layer deposition (ALD) as well as chemical vapor deposition (CVD).

In particular, when a molybdenum-containing thin film is formed using the molybdenum precursor compound of the present invention, a molybdenum-containing metal film, a molybdenum-containing oxide thin film, or a molybdenum-containing nitride thin film can be deposited by atomic layer deposition, and the thickness and composition of the thin film can be precisely adjusted by controlling the process temperature. In addition, it is possible to form a thin film with excellent coverage and uniform thickness and composition even on a complex-shaped substrate using the molybdenum precursor compound of the present invention, whereby the characteristics of a semiconductor device can be enhanced.

Accordingly, the molybdenum precursor compound of the present invention can be advantageously used with excellent properties depending on its uses in various fields such as memory devices, logic devices, and display devices. In particular, it can be very effectively utilized in electronic devices that require excellent properties and coverage with an extremely thin thickness.

### BRIEF DESCRIPTION OF DRAWINGS

FIG. 1 is a ¹H-NMR spectrum of the molybdenum precursor compound prepared in the Example of the present application.

FIG. 2 is a thermogravimetric analysis (TGA) graph of the molybdenum precursor compounds prepared in the Example and the Comparative Examples of the present invention.

FIGS. 3 to 6 are graphs showing the deposition characteristics of molybdenum-containing nitride thin films with respect to the supply and purge time of the molybdenum precursor prepared in the Example of the present invention and ammonia gas.

FIG. 7 is a graph showing the deposition characteristics of molybdenum-containing nitride thin films with respect to the process cycle of the molybdenum precursor prepared in the Example of the present invention and ammonia gas.

FIGS. 8 to 11 are transmission electron microscope photographs showing the thickness of the molybdenum-containing nitride thin films with respect to the process cycle of the molybdenum precursor prepared in the Example of the present invention and ammonia gas.

FIGS. 12a to 13b are transmission electron microscope photographs and scanning probe microscope photographs showing the thickness and surface roughness of the molybdenum-containing nitride thin films with respect to the process cycle of the molybdenum precursor prepared in the Example of the present invention and ammonia gas.

FIG. 14 is a transmission electron microscope photograph showing the step coverage of a molybdenum-containing nitride thin film with respect to the target thickness.

### BEST MODE FOR CARRYING OUT THE INVENTION

Hereinafter, the present application will be described in more detail.

The advantages and features of the present invention and the methods of achieving them will become apparent with reference to the embodiments described hereinafter. However, the present invention is not limited to the embodiments described below, but may be embodied in various different forms. These embodiments are provided so that the disclosure of the present invention will be thorough and complete, and will fully convey the scope of the invention to those skilled in the art. The invention is defined by only the scope of the claims.

In addition, in the present specification, in the case where an element is mentioned to be formed “on” another element, it means not only that one element is directly formed “on” another element, but also that other element(s) is interposed between them.

In the present specification, when a part is referred to as “comprising” an element, it is to be understood that the part may comprise other elements as well, rather than exclude other elements, unless otherwise indicated.

All numbers and expressions related to the quantities of components, reaction conditions, and the like used herein are to be understood as being modified by the term “about,” unless otherwise indicated.

In the present specification, each of the terms “film” and “thin film” refers to both “film” and “thin film,” unless otherwise specified.

### Molybdenum Precursor Compound

According to an embodiment of the present invention, there is provided a molybdenum precursor compound represented by the following Formula 1.

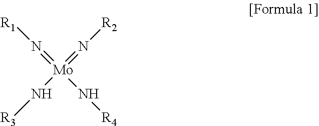

In Formula 1, R₁ to R₄ are each independently selected from substituted or unsubstituted C₅-C₁₀ linear and branched alkyl groups.

For example, in Formula 1, R₁ to R₄ may each independently be linear or branched pentyl (amyl), hexyl, heptyl, octyl, nonyl, or decyl, which may be unsubstituted or substituted with one or more substituents. The substituent may be, for example, one or more selected from the group consisting of halogen elements (F, Cl, Br, and I), hydroxy (OH), C₁-C₆ alkylamino, and C₁-C₆ alkoxy, but it is not limited thereto.

As a specific example, the molybdenum precursor compound may be represented by the following Formula 2.

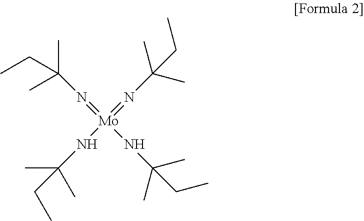

The molybdenum precursor compound according to an embodiment of the present invention is present in a liquid state at room temperature, which is advantageous for the manufacturing process, has a low resistivity, and is excellent in thermal stability. It is possible to readily form a molybdenum-containing thin film by atomic layer deposition (ALD) as well as chemical vapor deposition (CVD).

In particular, when a molybdenum-containing thin film is formed using the above molybdenum precursor compound, a molybdenum-containing metal film, a molybdenum-containing oxide thin film, or a molybdenum-containing nitride thin film can be deposited by atomic layer deposition, and the thickness and composition of the thin film can be precisely adjusted by controlling the process temperature. It is possible to form a thin film with excellent coverage and uniform thickness and composition even on complex-shaped substrates, whereby the characteristics of a semiconductor device can be enhanced.

The molybdenum precursor compound may have a TG₅₀ (° C.) of 180° C. to 300° C., in which TG50 is a temperature when the weight of the molybdenum precursor compound is reduced by 50% while it is heated from room temperature (25° C.) to 500° C. at a temperature elevation rate of 10° C./minute in thermogravimetric analysis (TGA). As a specific example, the TG₅₀ (° C.) may be 190° C. to 300° C., 195° C. to 300° C., 195° C. to 280° C., 195° C. to 260° C., 195° C. to 250° C., or 195° C. to 230° C.

According to an embodiment of the present invention, the molybdenum precursor compound has a percentage (% by weight) of the residual weight (W₅₀₀) at 500° C. relative to the initial weight (weight at 25° C.) of, for example, less than 20% by weight, for example, 15% by weight or less, for example, less than 15% by weight, for example, 13% by weight or less, for example, 12% by weight or less, for example, 10% by weight or less, for example, 8% by weight or less, for example, 7% by weight or less, for example, 5% by weight or less, for example, 4.5% by weight or less, for example, 3% by weight or less, for example, 2% by weight or less, for example, 1.5% by weight or less, for example, 1% by weight or less, or, for example, 0.8% by weight or less, as measured by thermogravimetric analysis (TGA).

The molybdenum precursor compound may have a weight reduction ratio (WR₅₀₀) of 80% or more according to the following Equation 1.

$${WR}_{500} ( \% ) = \frac{{W}_{25} - {W}_{500}}{{W}_{25}} \times 100 \qquad [ Equation 1 ]$$

In Equation 1, W₂₅ is the initial weight of the molybdenum precursor compound at 25° C., and W₅₀₀ is the weight of the molybdenum precursor compound at 500° C. after the temperature is raised from 25° C. to 500° C. at a temperature elevation rate of 10° C./minute.

Specifically, the molybdenum precursor compound may have a weight reduction ratio (WR₅₀₀) of, for example, 85% or more, for example, 87% or more, for example, 88% or more, for example, 89% or more, for example, 90% or more, for example, 92% or more, for example, 93% or more, for example, 95% or more, for example, 97% or more, or, for example, 98% or more.

### Method for Preparing a Molybdenum Precursor Compound

According to an embodiment of the present invention, there is provided a method for preparing a molybdenum precursor compound represented by the above Formula 1.

The molybdenum precursor compound represented by Formula 1 may be prepared by various methods.

The method for preparing a molybdenum precursor compound according to an embodiment of the present invention comprises reacting a compound represented by the following Formula A with a compound represented by the following Formula B and a compound represented by the following Formula C in a solvent:

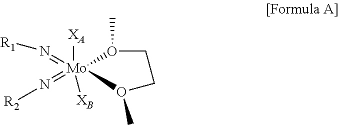

In Formula A, R₁ and R₂ are each independently selected from substituted or unsubstituted C₅-C₁₀ linear and branched alkyl groups, and X_{A} and X_{B} are each independently a halogen element,

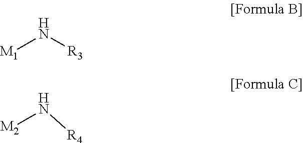

In Formulae B and C, M₁ and M₂ are each independently an alkali metal or alkaline earth metal, and R₃ and R₄ are each independently selected from substituted or unsubstituted C₅-C₁₀ linear and branched alkyl groups.

In Formula A, X_{A} and X_{B} may each independently be F, Cl, Br, or I; and, in Formulae B and C, M₁ and M₂ may each independently be Li, Na, K, or Mg.

Specifically, a molybdenum precursor compound represented by Formula 1 may be prepared by a reaction as shown in the following Reaction Scheme 1.

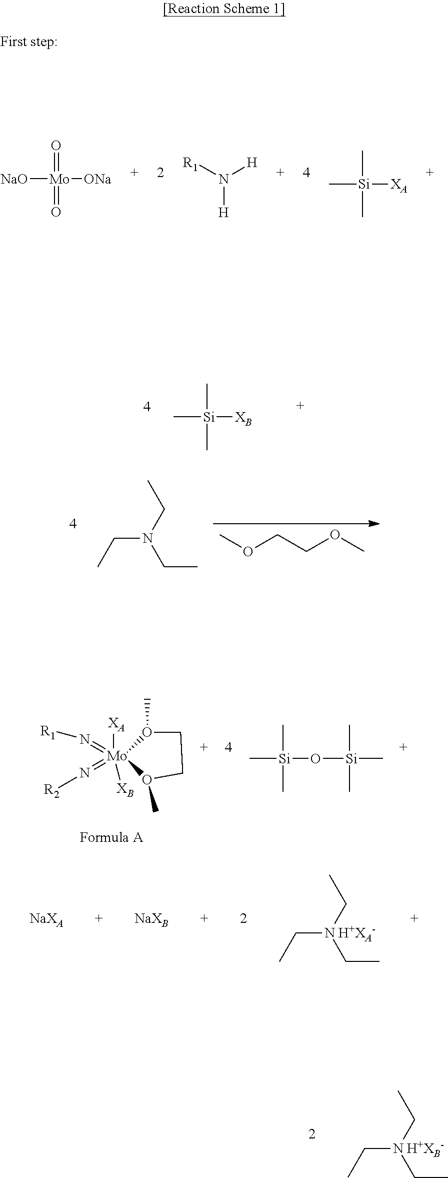

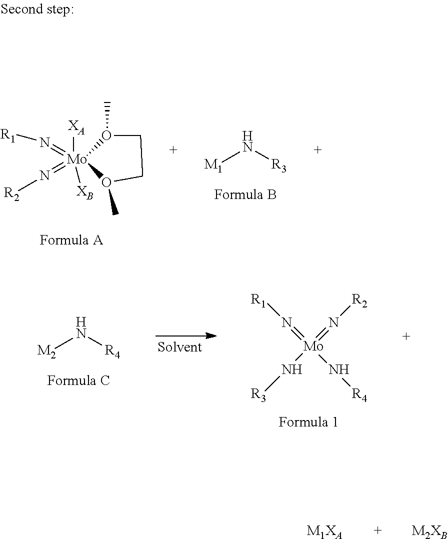

In Reaction Scheme 1,

X_{A}, X_{B}, M₁, M₂, R₁, R₂, R₃ are ad defined above.

As shown in Reaction Scheme 1, the molybdenum, precursor compound of Formula may be readily prepare by carrying out a reaction (e.g., an amine substitution reaction, i.e., halide-primary amine substitution reaction) of a halide (compound of Formula A) with primary amines (compounds of Formulae B and C) in a solvent (e.g., a polar solvent, a non-polar solvent, or a mixed solvent thereof), followed by purification thereof.

The ratio of the total number of moles of the compounds represented by Formulae B and C to the number of moles of the compound represented by Formula A may be 2 to 3, for example, 2 to 2.5.

The halide-primary amine substitution reaction may be carried out in a solvent at a temperature of 25° C. to 50° C. for 12 to 24 hours.

The solvent used in the first step of Reaction Scheme 1 may be dimethoxyethane containing oxygen for the synthesis of an adduct.

The solvent used in the second step of Reaction Scheme 1 may comprise one or more selected from the group consisting of an alkane having 5 to 8 carbon atoms, toluene, ethers, tetrahydrofuran, and mono- to tetra-ethylene glycol dimethyl ethers. For example, the solvent used in the second step of Reaction Scheme 1 may comprise hexane, pentane, toluene, or combinations thereof. Specifically, it is preferable to use hexane because its boiling point is stable at 78° C.

According to an embodiment of the present invention, the molybdenum precursor compound may be a compound represented by the above Formula 2. In the compound represented by Formula 2, R₁ and R₂ are each a tertiary-amyl (t-Amyl) group. As shown in Reaction Scheme 1, the bis(tertiary-amylimino)dichloromolybdenum-dimethoxyethane adduct (^{t}AmylN)₂MoCl₂(C₄H₁₀O₂) and tertiary-amyl lithium (Li-NH^{t}Amyl) may be slowly added dropwise to a solvent in which tetrahydrofuran, a polar solvent, and hexane, a non-polar solvent, have been mixed, followed by refluxing and stirring the reaction solution for 12 hours. Upon completion of the reaction, the solvent is removed under a reduced pressure, and the product is distilled under a reduced pressure to obtain a molybdenum precursor compound of the above Formula 2. In order to suppress the decomposition reaction by moisture or oxygen during the reaction, the reaction may be carried out under a nitrogen (N₂) or argon (Ar) stream.

### Molybdenum-Containing Thin Film

In addition, the present invention provides a composition for forming a molybdenum-containing thin film that comprises the molybdenum precursor compound.

According to an embodiment of the present invention, there is provided a molybdenum-containing thin film formed using a molybdenum precursor compound represented by Formula 1 or a composition thereof.

Specifically, the molybdenum-containing thin film may be at least one selected from the group consisting of a molybdenum-containing metal film, a molybdenum-containing oxide thin film, and a molybdenum-containing nitride thin film.

For example, the molybdenum precursor compound may be used to deposit a molybdenum-containing metal film, a molybdenum-containing oxide thin film, or a molybdenum-containing nitride thin film on a substrate by atomic layer deposition.

When a molybdenum-containing metal film, a molybdenum-containing oxide thin film, or a molybdenum-containing nitride thin film is deposited by atomic layer deposition, the process temperature can be controlled to precisely adjust the thickness and composition of the thin film; thus, it is possible to deposit a thin film with excellent coverage even on a complex-shaped substrate and to enhance the thickness uniformity and physical properties of the thin film.

In such an event, it is preferable to use the molybdenum precursor compound represented by the above Formula 1 as a molybdenum precursor compound for depositing a molybdenum-containing metal film, a molybdenum-containing oxide thin film, or a molybdenum-containing nitride thin film to be adopted in memory devices, logic devices, and display devices.

In addition, the molybdenum-containing thin film according to an embodiment of the present invention may have a resistivity (μΩ·cm) of 12,000 μΩ·cm or less. For example, the molybdenum-containing thin film may have a low resistivity (μΩ·cm) of 11,000 μΩ·cm or less, 10,000 μΩ·cm or less, 9,000 μΩ·cm or less, 8,000 μΩ·cm or less, 7,000 μΩ·cm or less, 6,000 μΩ·cm or less, 5,000 μΩ·cm or less, 4,000 μΩ·cm or less, or 3,000 μΩ·cm or less. Specifically, the resistivity of the molybdenum-containing thin film may be 0 μΩ·cm to 12,000 μΩ·cm, 100 μΩ·cm to 12,000 μΩ·cm, or 1,000 μΩ·cm to 10,000 μΩ·cm.

### Method for Depositing a Molybdenum-Containing Thin Film

The present invention provides a method for depositing a molybdenum-containing thin film, which comprises depositing a molybdenum-containing thin film on a substrate using a molybdenum precursor compound.

In addition, according to the present invention, there is provided a method for depositing a thin film using a molybdenum precursor compound, which is characterized by using a molybdenum precursor compound represented by the above Formula 2, in which both R₁ and R₂ are an amyl group, as a molybdenum precursor compound for depositing a molybdenum-containing metal film, a molybdenum-containing oxide thin film, or a molybdenum-containing nitride thin film to be adopted in semiconductors, non-semiconductors, and display devices.

In the molybdenum precursor compound represented by the above Formula 2, the imino group attached to molybdenum forms a double bond with the molybdenum metal, thereby increasing the stability of the molybdenum precursor. The primary amines, in which hydrogen is attached to nitrogen, have good reactivity and can thus easily react on the surface to form a first layer, whereby a stable molybdenum-containing metal film, oxide thin film, or nitride thin film can be readily formed. In addition, since the same type of amyl group is bound to the amines, the same amyl group is formed in the mechanism where isomer impurities are generated by the migration of acidic hydrogen attached to the primary amine; thus, substantially no isomer impurities are generated, whereby a pure molybdenum precursor can be obtained.

Acidic hydrogen attached to the primary amine has good surface reactivity with a substrate and is thus easily adsorbed. Thus, it is advantageous for the formation of a molybdenum-containing metal film through a reaction with hydrogen (H₂) as a subsequent reaction material. It is also advantageous for the formation of an oxide thin film through a reaction with ozone (O₃), which has a strong oxidizing power, and the formation of a nitride thin film through a reaction with ammonia (NH₃), which has a strong nitriding power. In addition, it has high stability and can be deposited even at high temperatures, and the film density can also be increased. The molybdenum-containing metal film, oxide thin film, or nitride thin film of the present invention can be formed in a wide temperature range of 300° C. to 550° C. by this deposition mechanism. In addition, since it is present in a liquid state at room temperature, it can be appropriately used as a molybdenum precursor compound for depositing a molybdenum-containing metal film, a molybdenum-containing oxide thin film, or a molybdenum-containing nitride thin film by atomic layer deposition.

In addition, the present invention provides a method for depositing a molybdenum-containing metal film, a molybdenum-containing oxide thin film, or a molybdenum-containing nitride thin film using a molybdenum precursor compound.

The thickness of the molybdenum-containing metal film, molybdenum-containing oxide thin film, or molybdenum-containing nitride thin film of the present invention may be about 1 nanometer to several micrometers, which may vary in various ways depending on the application purposes, but it may not be limited thereto.

The molybdenum-containing metal film, molybdenum-containing oxide thin film, or molybdenum-containing nitride thin film of the present invention may be adopted in semiconductors, non-semiconductors, and display devices in various ways depending on the application purposes, but it may not be limited thereto.

The method of depositing the molybdenum precursor compound of the present invention comprises supplying a precursor composition for forming a molybdenum-containing metal film, a molybdenum-containing oxide thin film, or a molybdenum-containing nitride thin film in a gaseous state to a substrate accommodated in a deposition chamber to form a molybdenum-containing metal film, a molybdenum-containing oxide thin film, or a molybdenum-containing nitride thin film on the substrate, but it is not limited thereto.

The deposition method of a thin film may use any methods and apparatuses known in the art to which the present invention pertains; if necessary, it may be carried out using one or more additional reactant gases or the like. The substrate may be a silicon semiconductor wafer, a compound semiconductor wafer, and a plastic substrate (PI, PET, or PES), but it is not limited thereto. A substrate having holes or grooves may be used, and a porous substrate having a large surface area may be used.

Depositing a molybdenum-containing metal film, a molybdenum-containing oxide thin film, or a molybdenum-containing nitride thin film on a substrate may comprise what is carried out by chemical vapor deposition (CVD), such as metal organic chemical vapor deposition (MOCVD), or atomic layer deposition (ALD), but it may not be limited thereto. The metal organic chemical vapor deposition (MOCVD) or atomic layer deposition (ALD) may be carried out using a deposition apparatus, deposition conditions, and additional reaction gases known in the art.

Specifically, in the method for depositing a thin film using the molybdenum precursor according to the present invention, the molybdenum precursor compound is used as a precursor, by virtue of its low density and high thermal stability, for atomic layer deposition or chemical vapor deposition to form a molybdenum-containing metal film, a molybdenum-containing oxide thin film, or a molybdenum-containing nitride thin film on a substrate. In particular, according to the method of the present invention, it is possible to uniformly form a molybdenum-containing metal film, a molybdenum-containing oxide thin film, and a molybdenum-containing nitride thin film even on a substrate having patterns (grooves) with a thickness of several micrometers to tens of nanometer, a porous substrate, or a plastic substrate in a temperature range of 300° C. to 550° C., specifically 300° C. to 500° C., more specifically 350° C. to 450° C. Specifically, according to the method of the present invention, it is possible to uniformly form a molybdenum-containing metal film, a molybdenum-containing oxide thin film, and a molybdenum-containing nitride thin film on the entire surface (covering the deepest surface and the upper surface) of fine patterns (grooves) having an aspect ratio of about 1 to 50 or more and a width of about 1 μm to 10 nm or less.

In the method for depositing a thin film using the molybdenum precursor compound of the present invention, a substrate is first accommodated in a reaction chamber, and a molybdenum-containing metal film, a molybdenum-containing oxide thin film, or a molybdenum-containing nitride thin film can be formed on the substrate using the molybdenum precursor compound and a transport gas or diluent gas. Since these various thin films have different characteristics, it is desirable to have a wide temperature range for deposition. The temperature for depositing a thin film using the molybdenum precursor compound according to the present invention may be 300° C. to 550° C., specifically 300° C. to 500° C., more specifically 350° C. to 450° C. If the deposition temperature is within the above range, it can be applied to various fields such as memory devices, logic devices, and display devices. In an embodiment, the deposition may be carried out at a temperature of 300° C. to 550° C. by chemical vapor deposition (CVD) or atomic layer deposition (ALD). In addition, it is possible to use a single or mixed gas selected from argon (Ar), nitrogen (N₂), helium (He), and hydrogen (H₂) as the transport gas or diluent gas.

The molybdenum precursor compound may be delivered onto the substrate by at least one method selected from the group consisting of a bubbling method for forcibly vaporizing it using a transport gas or a diluent gas, a liquid delivery system (LDS) method for supplying it in a liquid phase at room temperature to be vaporized through a vaporizer; a vapor flow control (VFC) method for directly supplying the precursor using its vapor pressure; and a bypass method.

For example, if the vapor pressure is high, a vapor flow control (VFC) method may be used. If the vapor pressure is low, at least one supply method selected from the group consisting of a bypass method of vaporization by heating the vessel; and a method of bubbling using argon (Ar) or nitrogen (N₂) gas may be used.

More specifically, the delivery method comprises a bubbling method or a bypass method of vaporization by heating, in which the bubbling method may be carried out using a transport gas in a temperature range of room temperature to 150° C., for example, 100° C. to 150° C., and 0.1 Torr to 10 Torr, and the bypass method of vaporization by heating may be carried out using a vapor pressure of 0.1 Torr to 10 Torr in a temperature range of room temperature to 160° C., for example, 80° C. to 160° C.

In addition, in order to vaporize the molybdenum precursor compound, for example, argon (Ar) or nitrogen (N₂) gas may be used for the transportation thereof. Alternatively, during the deposition, thermal energy or plasma may be used, or a bias may be applied to the substrate.

In an embodiment, the molybdenum-containing thin film may comprise a molybdenum-containing metal film, and at least one selected from the group consisting of hydrogen (H₂), nitrogen (N₂), and ammonia (NH₃) may be used as a reaction gas during the deposition.

In another embodiment, the molybdenum-containing thin film may comprise a molybdenum-containing oxide thin film (e.g., MoO₂, MoO₃), and at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) may be used as a reaction gas during the deposition.

In another embodiment, the molybdenum-containing thin film may comprise a molybdenum-containing nitride thin film (e.g., MoN), and at least one selected from the group consisting of ammonia (NH₃), ammonia plasma (NH₃ plasma), hydrazine (N₂H₄), and nitrogen plasma (N₂ plasma) may be used as a reaction gas during the deposition.

According to an example, the supply time of the molybdenum precursor compound during the deposition may be 0.1 second to 20 seconds, specifically 0.5 second to 10 seconds, more specifically 1 second to 5 seconds. In addition, the supply time of the reaction gas such as ammonia during the deposition may be 1 second to 100 seconds, specifically 5 seconds to 80 seconds, more specifically 30 seconds to 60 seconds. In addition, the purge time of the molybdenum precursor compound during the deposition may be 1 second to 50 seconds, specifically 5 seconds to 40 seconds, more specifically 15 seconds to 30 seconds. In addition, the purge time of the reaction gas such as ammonia during the deposition may be 1 second to 50 seconds, specifically 3 seconds to 20 seconds, more specifically 5 seconds to 10 seconds.

In addition, the method according to the present invention may further comprise, after depositing a molybdenum-containing thin film on a substrate using the molybdenum precursor compound, at least one thermal treatment among rapid thermal treatment annealing (RTA) and furnace thermal treatment. The degree of crystallinity can be further improved by the additional thermal treatment step. The thermal treatment may be carried out in an argon or nitrogen atmosphere at a temperature of, for example, 400° C. to 500° C. for 200 seconds to 400 seconds.

The thickness of the molybdenum-containing thin film is not particularly limited, but it may be, for example, 10 Å to 900 Å, specifically 20 Å to 500 Å, more specifically 30 Å to 300 Å.

The surface roughness of the molybdenum-containing thin film is not particularly limited, but the RMS (root mean square) roughness may be, for example, 0.01 nm to 0.5 nm, specifically 0.1 nm to 0.5 nm, more specifically 0.1 nm to 0.2 nm or 0.2 nm to 0.3 nm.

### MODE FOR THE INVENTION

Hereinafter, the deposition of a thin film using the molybdenum precursor compound according to the present invention will be described in more detail through the following examples. However, this is only presented to help understand the present invention, and the present invention is not limited to the following examples.

### <Preparation Example 1> Bis(tertaryamylimino)dichloromolybdenum-dimethoxyethane adduct ((^{t}AmylN)₂MoCl₂(C₄H₁₀O₂))

A flame-dried 3-liter Schlenk flask was charged with about 300 g (about 1.46 moles) of sodium molybdate (Na₂MoO₄) and about 2,500 ml of dimethoxyethane (C₄H₁₀O₂), which was maintained at room temperature. While the mixture in the flask was stirred, about 589.69 g (about 5.827 moles) of triethylamine ((C₂H₅)₃N) and about 1,266.2 g (about 11.66 moles) of trimethylchlorosilane ((CH₃)₃SiCl) were sequentially added thereto slowly and dropwise. In such an event, a fume was generated, and a white solid was formed. About 255.21 g (about 2.91 moles) of tert-amylamine ((^{t}AmylNH₂) was slowly added dropwise to the flask, and the reaction solution was stirred under reflux for about 12 hours. Upon completion of the reaction, the salt formed during the reaction was removed through filtration, and the solvent and volatile side reactants were removed under a reduced pressure to obtain 593 g of a dark green solid.

¹H-NMR (400 MHz, C₆D₆, 25° C.): δ 3.40, (m, 6H, CH₃OCH₂CH₂OCH₃), δ 3.26 (s, 4H, CH₃OCH₂CH₂OCH₃), δ 1.74, δ 1.72 (q, 4H, (CH₃CH₂(CH₃)₂CN)Mo), δ 1.43 (s, 12H, (CH₃CH₂(CH₃)₂CN)Mo), δ 1.10, δ 1.09, δ 1.07 (t, 6H, (CH₃CH₂(CH₃)₂CN)Mo)

### <Example 1> Bis(tert-aryamylimino)bis(tert-aryamylamino) molybdenum ((^{t}AmylN)₂Mo(NH^{t}Amyl)₂)

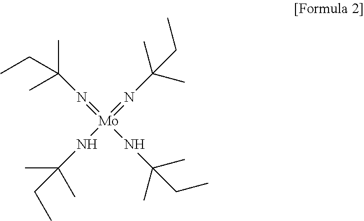

A flame-dried 2-liter Schlenk flask was charged with about 91.25 g (1.05 moles) of tert-amylamine (^{t}AmylNH₂) and about 1,000 ml of n-hexane (C₆H₁₄), and the temperature was maintained at about −70° C. to −50° C. About 290.2 g (about 1.05 moles) of n-butyl lithium (n-BuLi, 23%) was slowly added dropwise thereto using a cannula, the temperature was raised to room temperature, and the mixture was stirred for 3 hours to obtain Li-NH^{t}Amyl. Upon completion of the reaction, the solvent and volatile side reactants were removed under a reduced pressure to obtain a white solid. Then, 500 ml of tetrahydrofuran (THF, (CH₂)₄O) was added to dissolve the solid.

Another flame-dried 2-liter Schlenk flask was charged with about 213 g (0.5 mole) of the bis(tertaryamylimino)dichloromolybdenum-dimethoxyethane adduct ((^{t}AmylN)₂MoCl₂(C₄H₁₀O₂)) obtained in Preparation Example 1 and about 700 ml of tetrahydrofuran (THF, (CH₂)₄O), which was maintained at −70° C. to −50° C. Li-NH^{t}Amyl synthesized in advance and dissolved in tetrahydrofuran (THF, (CH₂)₄O) was slowly added dropwise thereto, and the temperature was slowly raised to room temperature, followed by stirring thereof under reflux for 12 hours. Upon completion of the reaction, the salt formed during the reaction was removed through filtration, and the solvent and volatile side reactants were distilled off under a reduced pressure to obtain about 149 g (yield: about 68%) of the target compound as an orange liquid.
Density: 1.20 g/mole (at 25° C.)
Boiling point (bp): 101° C. (0.4 Torr) (299.3° C. at 760 mmHg)
Viscosity: 26.61 cP (at 25° C.)

¹H-NMR (400 MHz, C₆D₆, 25° C.): δ 5.67 (s, 2H, Mo(NHC(CH₃)₂CH₂CH₃)), δ 1.70, δ 1.68 (q, 4H, Mo(NHC(CH₃)₂CH₂CH₃)), 1.55, δ 1.53 (q, 4H, (CH₃CH₂(CH₃)₂CN)Mo), δ 1.38 (s, 12H, Mo(NHC(CH₃)₂CH₂CH₃)), δ 1.30 (s, 12H, (CH₃CH₂(CH₃)₂CN)Mo), δ 1.07, δ 1.05, δ 1.03 (t, 6H, Mo(NHC(CH₃)₂CH₂CH₃), δ 0.95, δ 0.93, δ 0.91 (t, 6H, (CH₃CH₂(CH₃)₂CN)Mo)

### <Comparative Example 1> Tetrakis(ethylmethylamino)molybdenum(VI) (Mo(N(CH₃)(C₂H₅))₄)

A flame-dried 3-liter Schlenk flask was charged with about 305.8 g (about 1.097 mole) of n-butyl lithium and about 1 liter of n-hexane, and the temperature was lowered to about 0° C. About 66 g (1.116 moles) of HN(CH₃)(C₂H₅) was slowly added dropwise thereto, the temperature of the reaction solution was slowly raised to room temperature, and it was stirred for about 4 hours. Thereafter, about 250 ml of THF was added to the flask, which was then cooled to 0° C. MoCl₅ (about 50 g, about 0.183 mole) dissolved in n-hexane was slowly added dropwise thereto, and the reaction solution was stirred at room temperature for about 18 hours. Thereafter, it was further stirred under reflux for 2 hours to complete the reaction. Upon completion of the reaction, it was filtered through a celite pad and a glass frit, and the solvent was removed from the filtrate under a reduced pressure, which was then distilled under a reduced pressure to obtain about 16 g (yield: about 27%) of the target compound as a dark purple liquid.

### <Comparative Example 2> Bis(tertiarybutylimino)bis(dimethyl amino)molybdenum ((^{t}BuN)₂Mo(N(CH₃)₂)₂)

A flame-dried 2-liter Schlenk flask was charged with about 1,000 ml of n-hexane, about 58 g (about 0.22 mole) of n-butyl lithium (23%) was slowly added dropwise thereto using a cannula, and the temperature was maintained at about −10° C. to 0° C. About 29.75 g (about 0.66 mole) of dimethylamine (C₂H₆N) was added thereto by slowly bubbling, the temperature was raised to room temperature, and it was stirred for 3 hours to obtain Li—N(CH₃)₂.

Another flame-dried 2-liter Schlenk flask was charged with about 39 g (0.1 mole) of the bis(tertiarybutylimino)dichloromolybdenum-dimethoxyethane adduct (^{t}BuN)₂MoCl₂(C₄H₁₀O₂) and about 500 ml of toluene (C₇H₈), which was maintained at −30° C. to −20° C. Li—N(CH₃)₂ synthesized in advance was slowly added dropwise thereto, and the temperature was slowly raised to 50° C., followed by stirring thereof for 12 hours. Upon completion of the reaction, the salt formed during the reaction was removed through filtration, and the solvent and volatile side reactants were distilled off under a reduced pressure to obtain about 25 g (yield: about 69.6%) of the target compound as an orange liquid.

### <Test Example 1> Structural Analysis of the Molybdenum Precursor Compound

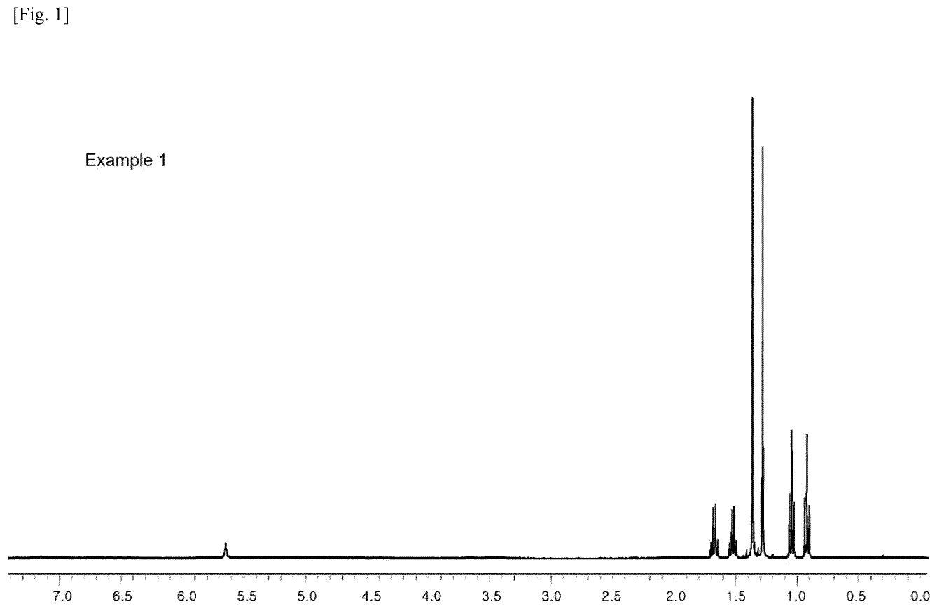

¹H-NMR analysis was carried out to analyze the structure of the molybdenum precursor compound prepared in Example 1. The result is shown in FIG. 1.

### <Test Example 2> Thermal Characteristic Analysis of the Molybdenum Precursor Compounds

Thermogravimetric analysis (TGA) was carried out to analyze the thermal characteristics of the molybdenum precursor compounds prepared in Example 1 and Comparative Examples 1 and 2. For thermogravimetric analysis (TGA), the change in weight of the molybdenum precursor compound (initially 10 mg) was measured while the temperature was raised from room temperature (25° C.) to about 500° C. at a temperature elevation rate of about 10° C./minute in a nitrogen (N₂) atmosphere. Specifically, the vaporization initiation temperature (° C.) of the molybdenum precursor compound and TG₅₀ (° C.), which is the temperature when the weight reduction of the molybdenum precursor compound is 50%, were measured. In addition, the weight reduction ratio (WR₅₀₀, %) of the molybdenum precursor compounds prepared in Example 1 of the present invention and Comparative Examples 1 and 2 was calculated by the following Equation 1:

$${WR}_{500} ( \% ) = \frac{{W}_{25} - {W}_{500}}{{W}_{25}} \times 100 \qquad [ Equation 1 ]$$

In Equation 1, W₂₅ is the initial weight of the molybdenum precursor compound at 25° C., and W₅₀₀ is the weight of the molybdenum precursor compound at 500° C. after the temperature is raised from 25° C. to 500° C. at a temperature elevation rate of 10° C./minute.

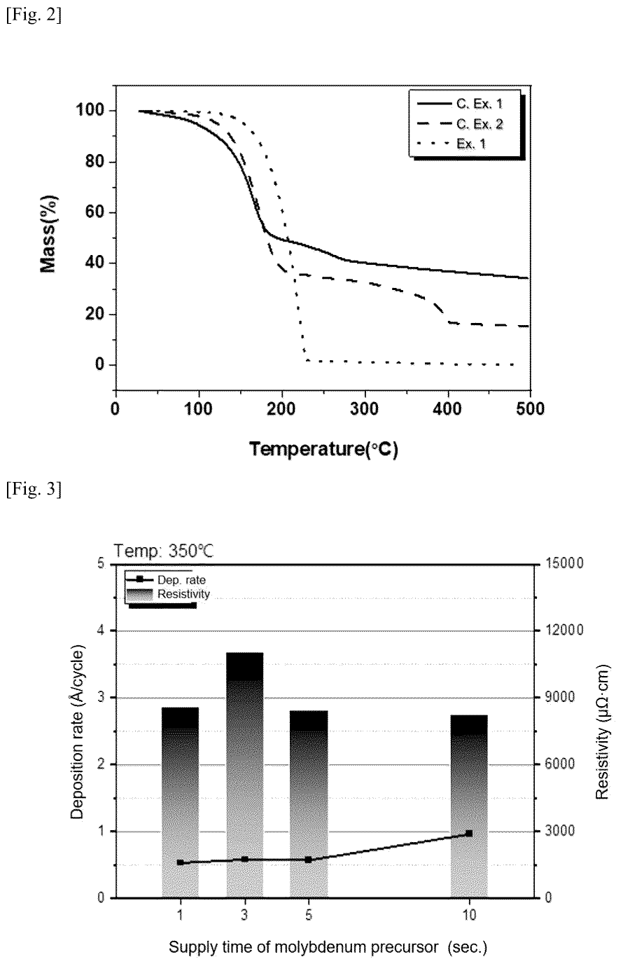

The measurement results of thermogravimetric analysis (TGA) are shown in FIG. 2 and Table 1 below.

TABLE 1

| | Vaporization initiation | | | |
|---|---|---|---|---|
| | temperature (° C.) | TG₅₀ (° C.) | W₅₀₀ (mg) | WR₅₀₀ (%) |
| Ex. 1 | 182.6 | 204.1 | 0.06 | 99.4 |
| C. Ex. 1 | 145.0 | 193.42 | 3.424 | 65.76 |
| C. Ex. 2 | 145.61 | 181.31 | 1.546 | 84.54 |

As can be seen from FIG. 2, in the molybdenum precursor compounds of Comparative Examples 1 and 2, a lot of residues were left due to poor thermal stability, or a two-step curve was shown due to the decomposition during the analysis. In contrast, the molybdenum precursor compound prepared in Example 1 of the present invention showed that the residues were volatilized without decomposition. These TGA characteristics show that it is 100% volatilized without decomposition by heating, indicating sufficient volatility to be applied to a process using ALD.

In addition, as can be seen from Table 1, most of the molybdenum precursor compound of Example 1 of the present invention was vaporized at around 200° C., and TG₅₀ (° C.), which is the temperature when the weight reduction of the molybdenum precursor compound is 50%, was about 204.1° C.

In addition, in particular, in the molybdenum precursor compound of Example 1, the residual weight (W₅₀₀) of the molybdenum precursor compound at about 500° C. was about 0% by weight to 1.3% by weight relative to the initial weight (10 mg). In contrast, in the molybdenum precursor compounds in Comparative Examples 1 and 2, the residual weight (W₅₀₀) thereof at about 500° C. was about 15% to 35% by weight relative to the initial weight (10 mg), which was remarkably higher than that of the molybdenum precursor compound of the Example.

Therefore, the molybdenum precursor compound of Example 1 had a very excellent weight reduction ratio (WR₅₀₀) of about 99% or more. In contrast, in the molybdenum precursor compounds of Comparative Examples 1 and 2, the weight reduction ratio (WR₅₀₀) was significantly reduced to about 65% to 85% as compared with Example 1.

Therefore, the molybdenum precursor compound of the present invention can show excellent volatility; and it is confirmed to be an excellent precursor that can form a molybdenum-containing metal film, oxide thin film, and nitride thin film in a temperature range of, in particular, 300° C. to 550° C., for example, 300° C. to 350° C., 350° C. to 400° C., 400° C. to 450° C., 450° C. to 500° C., or 500° C. to 550° C.

### <Test Example 3> Deposition Characteristics of the Molybdenum Precursor Compounds with Ammonia Gas

The molybdenum precursor compound prepared in Example 1 was used in an atomic layer deposition (ALD) process. Ammonia gas was used as a reaction gas to deposit a molybdenum nitride thin film. A silicon oxide substrate (thickness: 1,000 Å) whose surface had been washed with flowing purified water was used as a substrate for deposition. The prepared silicon oxide substrate was loaded into the reactor of CN1 equipment equipped with a showerhead-type device, and the reactor was heated to 350° C. at a pressure of about 2 Torr. The ALD cycle was set to 100 times, and the temperature of the substrate was set to 350° C. to check the characteristics of the molybdenum nitride thin film with respect to the temperature of the substrate. The molybdenum precursor compounds were each put in a canister made of stainless steel and heated to a temperature of about 110° C. The vaporized precursor was transported to the reactor using argon (Ar) gas as a carrier gas. To transport the molybdenum precursor compound to the reactor, argon (Ar) gas was used as a carrier gas for the precursor compound at a flow rate of 200 sccm, and 1,000 sccm of argon gas was used together to maintain the pressure of the reactor. Ammonia gas was used at a flow rate of 500 sccm, and argon gas of 1,000 sccm was used together to maintain the pressure of the reactor. Here, the process pressure of the reactor was measured to be about 2.3 Torr.

In order to confirm the optimized resistivity characteristics of a molybdenum-containing nitride thin film, the deposition process was carried out by adjusting the supply time and purge time of the molybdenum precursor compound and ammonia gas. The ALD cycle for controlling the supply time of the molybdenum precursor compound was as follows: 1, 3, 5, and 10 seconds for precursor supply, 10 seconds for precursor purge, 5 seconds for ammonia gas supply, and 10 seconds for ammonia gas purge. The ALD cycle for controlling the supply time of ammonia gas was as follows: 1 second for precursor supply, 5 seconds for precursor purge, 5, 10, 20, and 60 seconds for ammonia gas supply, and 5 seconds for ammonia gas purge. The ALD cycle for controlling the purge time of the molybdenum precursor compound was as follows: 1 second for precursor supply, 5, 10, and 20 seconds for precursor purge, 60 seconds for ammonia gas supply, and 5 seconds for ammonia gas purge. The ALD cycle for controlling the purge time of ammonia gas was as follows: 1 second for precursor supply, 5 seconds for precursor purge, 60 seconds for ammonia gas supply, and 5, 10, and 20 seconds for ammonia gas purge. In addition, to analyze the change in resistivity with respect to the thickness of a thin film, the deposition cycle was set to 38, 100, 140, 170, 180, and 250 cycles.

The sheet resistivity (μΩ/sq) of the molybdenum nitride thin film deposited on the silicon oxide thin film substrate was measured using a 4PPS (4-point probe system) of AIT Co., Ltd., and the thickness thereof was measured using an ellipsometer and a transmission electron microscope of J.A Woollam.

The thickness of the molybdenum nitride thin film with respect to the supply time of the molybdenum precursor compound was 53.0 Å for 1 second, 58.2 Å for 3 seconds, 56.5 Å for 5 seconds, and 95.9 Å for 10 seconds. Resistivity (μΩ·cm) was calculated from the thickness and sheet resistance values. The results are shown in FIG. 3.

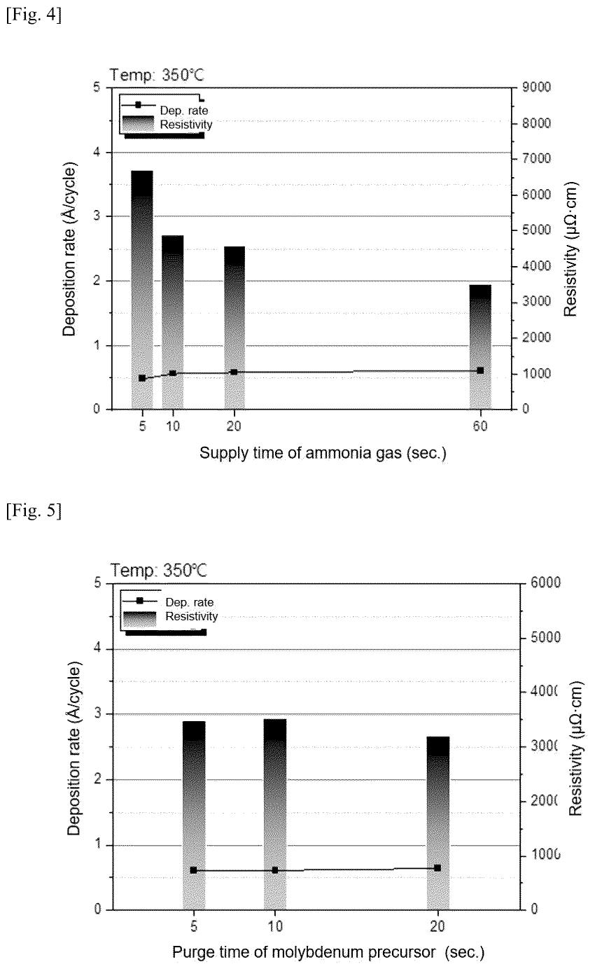

The thickness of the molybdenum nitride thin film with respect to the supply time of ammonia gas was 48.2 Å for 5 seconds, 55.7 Å for 10 seconds, 58.2 Å for 20 seconds, and 60.7 Å for 60 seconds. Resistivity (μΩ·cm) was calculated from the thickness and sheet resistance values. The results are shown in FIG. 4.

The thickness of the molybdenum nitride thin film with respect to the purge time of the molybdenum precursor compound was 60.7 Å for 5 seconds, 60.7 Å for 10 seconds, and 64.3 Å for 20 seconds. Resistivity (μΩ·cm) was calculated from the thickness and sheet resistance values. The results are shown in FIG. 5.

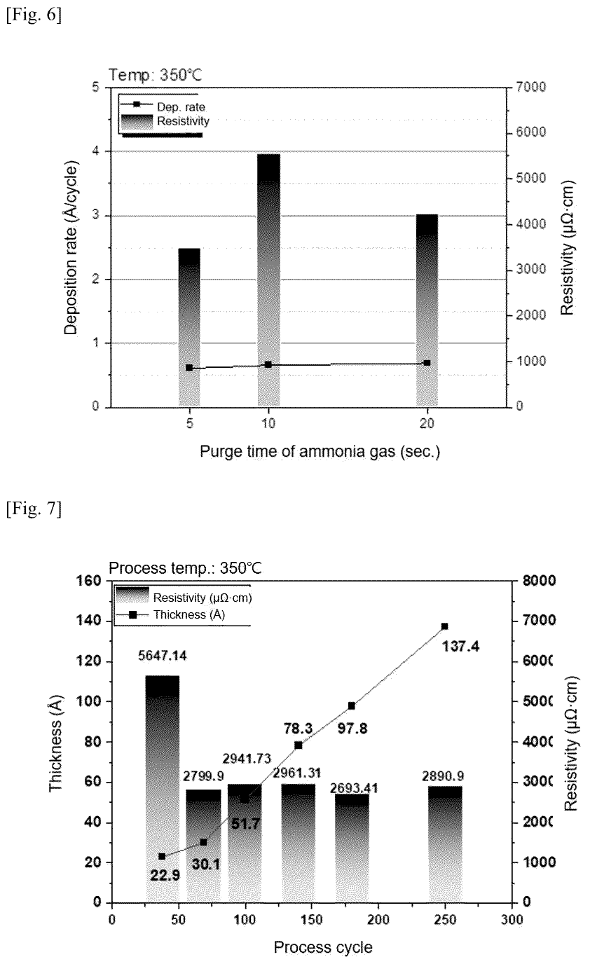

The thickness of the molybdenum nitride thin film with respect to the purge time of ammonia gas was 60.7 Å for 5 seconds, 65.6 Å for 10 seconds, and 69.2 Å for 20 seconds. Resistivity (μΩ·cm) was calculated from the thickness and sheet resistance values. The results are shown in FIG. 6.

Based on the above results, the process for optimizing the resistivity characteristics of the molybdenum-containing nitride thin film may be as follows: a precursor supply time of about 1 second, a precursor purge time of about 20 seconds, an ammonia gas supply time of about 60 seconds, and an ammonia purge time of about 5 seconds.

The physical properties or deposition characteristics of the molybdenum-containing nitride film using the molybdenum precursor compound prepared by the method of Example 1 were confirmed.

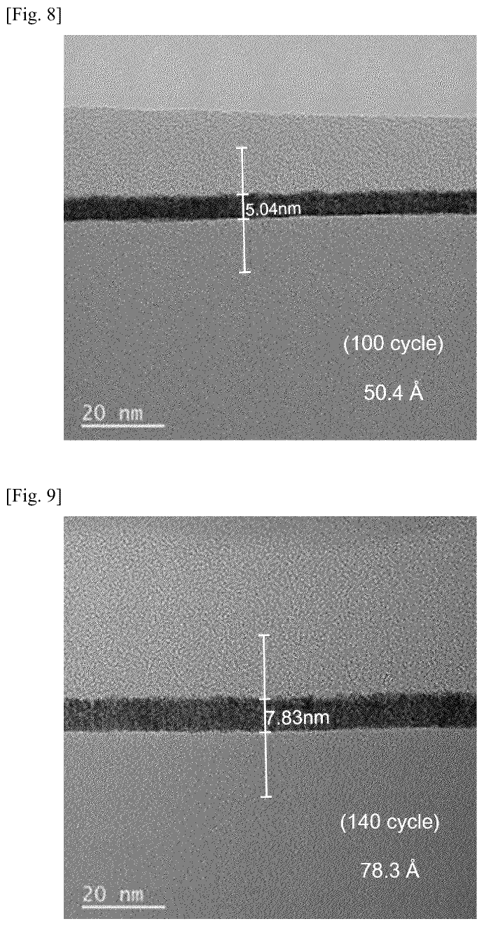

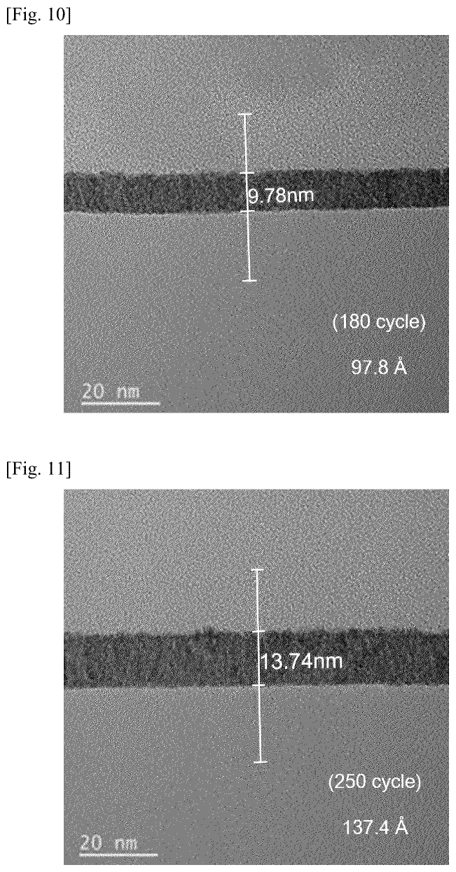

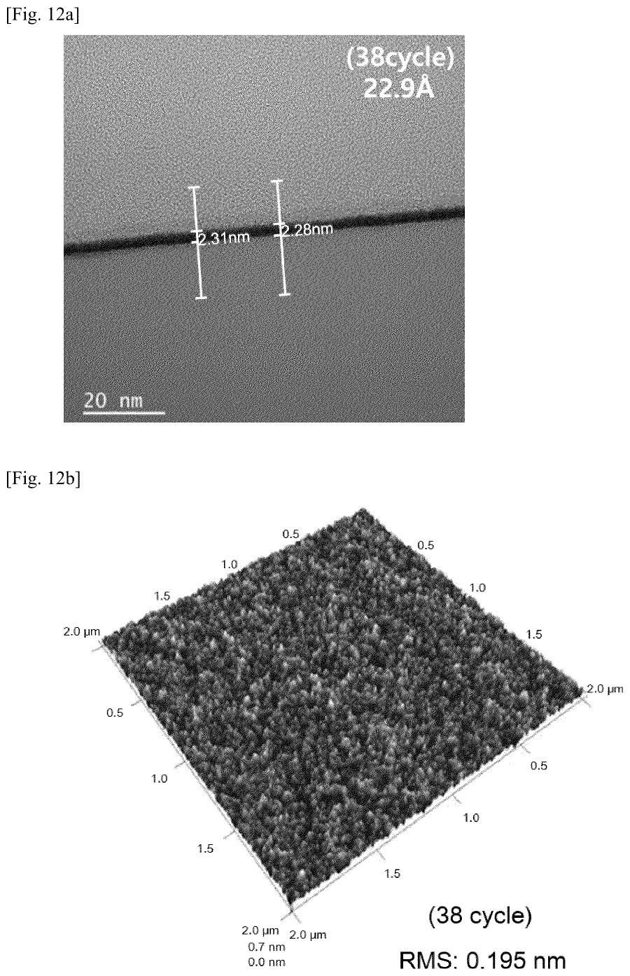

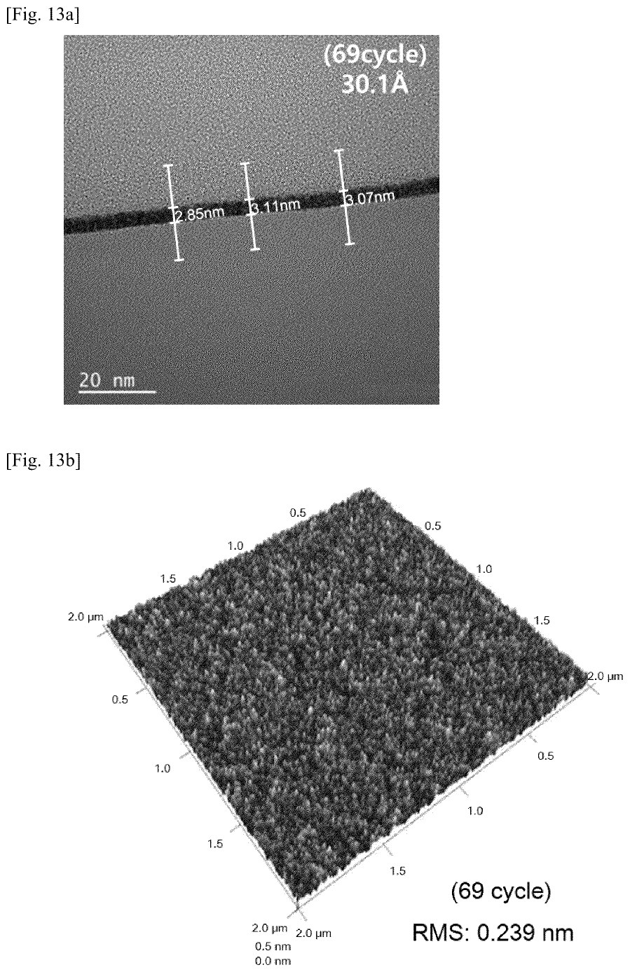

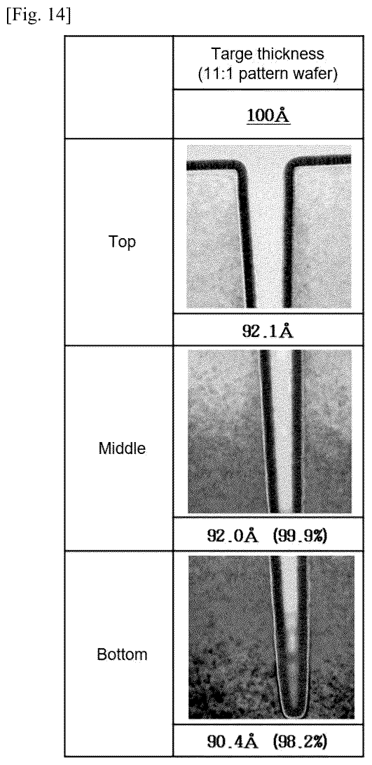

The resistivity with respect to the thickness of the thin film is shown in FIG. 7. In addition, the results of transmission electron microscopy measurement are shown in FIGS. 8, 9, 10, and 11 to confirm the thickness of the molybdenum-containing nitride film deposited through 100 cycles, 140 cycles, 180 cycles, and 250 cycles. In addition, the results of transmission electron microscopy and scanning probe microscope (atomic force microscope) measurements are shown in FIGS. 12a to 13b to confirm the surface roughness of the molybdenum-containing nitride film deposited through 38 cycles and 69 cycles. In addition, the results of transmission electron microscope measurement are shown in FIG. 14 to confirm the step coverage of the molybdenum-containing nitride film deposited on an 11:1 pattern wafer with a thin film thickness of 100 Å.

As can be seen from FIG. 3, when the supply time of the molybdenum precursor was 1 to 5 seconds, the deposition rate remained constant, and the resistivity values with respect to the change in supply time of the molybdenum precursor (1, 3, 5, and 10 seconds) were very low at 8,562, 11,039, 8,442, and 8,242 μΩ·cm, respectively.

As can be seen from FIG. 4, when the supply time of ammonia gas was 5 seconds or longer, the deposition rate remained constant, and the resistivity values with respect to the change in supply time of ammonia gas (5, 10, 20, and 60 seconds) were very low at 6,694, 4,886, 4,563, and 3,484 μΩ·cm, respectively.

As can be seen from FIG. 5, when the purge time of the molybdenum precursor was 5 to 20 seconds, the deposition rate remained constant, and the resistivity values with respect to the change in purge time of the molybdenum precursor (5, 10, and 20 seconds) were very low at 3,484, 3,512, and 3,198 μΩ·cm, respectively.

As can be seen from FIG. 6, when the purge time of ammonia gas was 5 to 20 seconds, the deposition rate remained constant, and the resistivity values with respect to the change in purge time of ammonia gas (5, 10, and 20 seconds) were very low at 3,484, 5,553, and 4,226 μΩ·cm, respectively.

As can be seen from FIG. 7, the change in resistivity with respect to the thickness of the thin film maintained linear when the process cycle was 38 to 250. The resistivity values with respect to the thickness of the thin film (22.9, 30.1, 51.7, 78.3, 97.8, and 137.4 Å) were very low at 5,647.14, 2,799.90, 2,941.73, 2,961.31, 2,693.41, and 2,890.90 μΩ·cm, respectively, after 30.1 Å.

As can be seen from FIGS. 8, 9, 10, and 11, the thickness measurement values of the transmission electron microscope with respect to the deposition process cycle (100, 140, 180, and 250 cycles) were 50.4 Å, 78.3 Å, 97.8 Å, and 137.4 Å.

As can be seen from FIGS. 12a to 13b, the thickness and surface roughness of the transmission electron microscope and scanning probe microscope (atomic force microscope) with respect to the deposition process cycle (38 and 69 cycles) were 0.195 nm for the thickness of 22.9 Å and 0.239 nm for the thickness of 30.1 Å.

As can be seen from FIG. 14, the step coverage of the molybdenum-containing nitride film according to the target thickness measured using a transmission electron microscope was such that the thickness of the lower part relative to the upper part was about 98.2% when the target thickness was 100 Å for an 11:1 pattern.

### <Test Example 4> Comparison of Crystallization Characteristics of a Dielectric Film Through the Formation of a Molybdenum Nitride Film

The molybdenum precursor compound prepared in Example 1 was used in an atomic layer deposition (ALD) process. Ammonia gas was used as a reaction gas to deposit a molybdenum nitride thin film. In addition, a substrate on which a high-k dielectric film (ZrO₂ film) had been deposited in advance on a TiN electrode was used. The prepared substrate was loaded into the reactor of CN1 equipment equipped with a showerhead-type device, and the reactor was heated to 350° C. at a pressure of about 2 Torr. The molybdenum precursor compounds were each put in a canister made of stainless steel and heated to a temperature of about 110° C. The vaporized precursor was transported to the reactor using argon (Ar) gas as a carrier gas. To transport the molybdenum precursor compound to the reactor, argon (Ar) gas was used as a carrier gas for the precursor compound at a flow rate of 200 sccm, and 1,000 sccm of argon gas was used together to maintain the pressure of the reactor. Ammonia gas was used at a flow rate of 500 sccm, and argon gas of 1,000 sccm was used together to maintain the pressure of the reactor. Here, the process pressure of the reactor was measured to be about 2.3 Torr. The thickness of the deposited thin film was fixed at 35 Å, and the temperature was set to 350° C. to check the crystallinity characteristics of the dielectric film. In addition, as a subsequent process, rapid thermal treatment annealing (RTA) and thermal treatment in a furnace were carried out.

The thermal treatment conditions are shown in Table 2.

TABLE 2

| | | Temp. | Atmosphere | Time |
|---|---|---|---|---|
| Deposition temp. | | 350° C. | — | — |
| Thermal | Furnace | 500° C. | Argon (Ar) | 400 sec. |
| treatment | Rapid thermal | | Nitrogen (N₂) | |
| method | treatment (RTA) | | | |

The crystallinity characteristics of the dielectric film (ZrO₂) according to the subsequent process are shown in Table 3.

TABLE 3

| | | MoN (thickness 35 Å) | | | |
|---|---|---|---|---|---|
| | Ref. | Condition 1 | Condition 2 | Condition 3 | Condition 4 |
| Upper electrode | TiN | MoN | MoN | MoN | No upper |
| | | deposition | deposition + | deposition + | electrode |
| | | | rapid thermal | furnace | |
| | | | treatment (RTA) | | |
| XRD area | 870.7 | 746.5 | 946.5 | 888.2 | 119.5 |
| (2θ: 30.2°) | | | | | |
| Crystallinity difference | — | −14.30% | +8.70% | +2% | −86.30% |
| (vs. TiN) | | | | | |

As can be seen from Table 3, when a molybdenum-containing nitride film was deposited on a dielectric film (ZrO₂ film), which was subjected to the subsequent thermal treatment, and the crystallinity of the dielectric film (ZrO₂ film) was analyzed as the area using X-ray diffraction analysis (XRD), the crystallinity was improved by +8.7% with the rapid thermal treatment method and improved by about 2% with the furnace method.

Through the above experiments, it was possible to form a molybdenum nitride film with a low resistivity from the molybdenum precursor compound of the present invention using a thermal ALD deposition process without plasma. This indicates that the molybdenum precursor of the present invention is an excellent precursor that can be used as a gate electrode used in DRAM or NAND flash.

1. A molybdenum precursor compound represented by the following Formula 1: 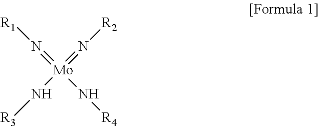
in Formula 1, R₁ to R₄ are each independently selected from substituted or unsubstituted C₅-C₁₀ linear and branched alkyl groups.

2. The molybdenum precursor compound of claim 1, which is represented by the following Formula 2:

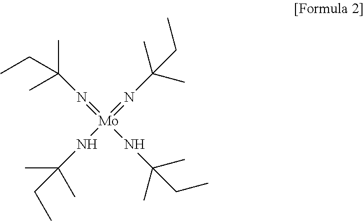

3. The molybdenum precursor compound of claim 1, wherein the molybdenum precursor compound has a TG₅₀ (° C.) of 180° C. to 300° C., in which TG50 is a temperature when the weight of the molybdenum precursor compound is reduced by 50% while it is heated from room temperature to 500° C. at a temperature elevation rate of 10° C./minute in thermogravimetric analysis (TGA).

4. The molybdenum precursor compound of claim 1, wherein the molybdenum precursor compound has a weight residual ratio (WR₅₀₀) of 80% or more according to the following Equation 1:
$${WR}_{500} ( \% ) = \frac{{W}_{25} - {W}_{500}}{{W}_{25}} \times 100 \qquad [ Equation 1 ]$$
in Equation 1, W₂₅ is the initial weight of the molybdenum precursor compound at 25° C., and W₅₀₀ is the weight of the molybdenum precursor compound at 500° C. after the temperature is raised from 25° C. to 500° C. at a temperature elevation rate of 10° C./minute.

5. A composition for forming a molybdenum-containing thin film, which comprises the molybdenum precursor compound of claim 1.

6. A method for preparing a molybdenum precursor compound represented by the following Formula 1, which comprises reacting a compound represented by the following Formula A with a compound represented by the following Formula B and a compound represented by the following Formula C in a solvent: 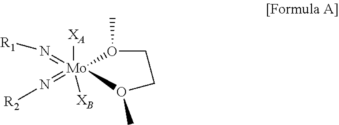
in Formula A, R₁ and R₂ are each independently selected from substituted or unsubstituted C₅-C₁₀ linear and branched alkyl groups, and X_{A} and X_{B} are each independently a halogen element, 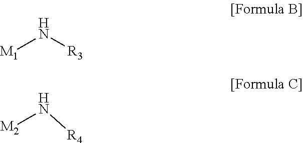
in Formulae B and C, M₁ and M₂ are each independently an alkali metal or alkaline earth metal, and R₃ and R₄ are each independently selected from substituted or unsubstituted C₅-C₁₀ linear and branched alkyl groups, and 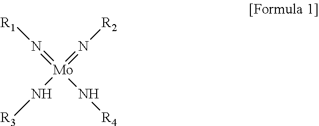
in Formula 1, R₁ to R₄ are each independently selected from substituted or unsubstituted C₅-C₁₀ linear and branched alkyl groups.

7. The method for preparing a molybdenum precursor compound of claim 6, wherein X_{A} and X_{B} are each independently F, Cl, Br, or I; and, in Formulae B and C, M₁ and M₂ are each independently Li, Na, K, or Mg.

8. The method for preparing a molybdenum precursor compound of claim 6, wherein the solvent comprises one or more selected from the group consisting of an alkane having 5 to 8 carbon atoms, toluene, ethers, tetrahydrofuran, and mono- to tetra-ethylene glycol dimethyl ethers.

9. A molybdenum-containing thin film formed using the molybdenum precursor compound of claim 1.

10. The molybdenum-containing thin film of claim 9, wherein the molybdenum-containing thin film has a resistivity of 12,000 μΩ·cm or less.

11. The molybdenum-containing thin film of claim 9, wherein the molybdenum-containing thin film is at least one selected from the group consisting of a molybdenum-containing metal film, a molybdenum-containing oxide thin film, and a molybdenum-containing nitride thin film.

12. A method for depositing a molybdenum-containing thin film, which comprises depositing a molybdenum-containing thin film on a substrate using the molybdenum precursor compound of claim 1.

13. The method for depositing a molybdenum-containing thin film of claim 12, wherein the deposition is carried out at a temperature of 300° C. to 550° C. by chemical vapor deposition (CVD) or atomic layer deposition (ALD).

14. The method for depositing a molybdenum-containing thin film of claim 12, wherein the molybdenum precursor compound is delivered onto the substrate by at least one selected from the group consisting of a bubbling method, a liquid delivery system (LDS) method, a vapor flow control (VFC) method, and a bypass method.

15. The method for depositing a molybdenum-containing thin film of claim 12, wherein, during deposition, thermal energy or plasma is used, or a bias is applied to the substrate.

16. The method for depositing a molybdenum-containing thin film of claim 12, wherein the molybdenum-containing thin film comprises a molybdenum-containing metal film, and a reaction gas comprising at least one selected from the group consisting of hydrogen (H₂), nitrogen (N₂), and ammonia (NH₃) is used during deposition.

17. The method for depositing a molybdenum-containing thin film of claim 12, wherein the molybdenum-containing thin film comprises a molybdenum-containing oxide thin film, and a reaction gas comprising at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) is used during deposition.

18. The method for depositing a molybdenum-containing thin film of claim 12, wherein the molybdenum-containing thin film comprises a molybdenum-containing nitride thin film, and a reaction gas comprising at least one selected from the group consisting of ammonia (NH₃), ammonia plasma (NH₃ plasma), hydrazine (N₂H₄), and nitrogen plasma (N₂ plasma) is used during deposition.

19. Use of the molybdenum precursor compound represented by the following Formula 1 for forming a molybdenum-containing thin film: 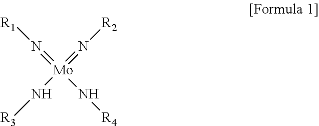
in Formula 1, R₁ to R₄ are each independently selected from substituted or unsubstituted C₅-C₁₀ linear and branched alkyl groups.

20. The use of claim 19, wherein the molybdenum precursor compound is represented by the following Formula 2: [chemical structure]
